(19) United States
(12) Patent Application Publication
(10) Pub. No.: US 2025/0129509 A1
(43) Pub. Date: Apr. 24, 2025

(54) AUXILIARY FLOW PLATE FOR THICKNESS AND CONCENTRATION UNIFORMITY ADJUSTABILITY

(71) Applicant: Applied Materials, Inc., Santa Clara, CA (US)

(72) Inventors: Zhepeng CONG, San Jose, CA (US); Alain DUBOUST, Sunnyvale, CA (US); Ala MORADIAN, Sunnyvale, CA (US); Tao SHENG, Santa Clara, CA (US); Nimrod SMITH, Cupertino, CA (US); Ashur J. ATANOS, San Jose, CA (US)

(21) Appl. No.: 18/382,429

(22) Filed: Oct. 20, 2023

(51) Int. Cl. C30B 25/14; C30B 25/10; C30B 25/12

(52) U.S. Cl. CPC C30B 25/14; C30B 25/10; C30B 25/12

(57) ABSTRACT

The present disclosure relates to an auxiliary flow plate for process kits and semiconductor processing chambers, and related methods and flow guides. In one or more embodiments, a chamber kit includes a liner, a first plate, and a second plate. The liner includes an inner face, a first ledge disposed along the inner face, and a second ledge disposed along the inner face. The second ledge is spaced from the first ledge along the inner face. The first plate is sized and shaped to be disposed within the liner on the first ledge. The second plate is sized and shaped to be disposed within the liner on the second ledge.

### BACKGROUND

### Field

The present disclosure relates to an auxiliary flow plate for process kits and semiconductor processing chambers, and related methods and flow guides.

### Description of the Related Art

Semiconductor substrates are processed for a wide variety of applications, including the fabrication of integrated devices and micro-devices. One method of processing substrates includes depositing a material, such as a dielectric material or a semiconductive material, on an upper surface of the substrate. The material may be deposited in a lateral flow chamber by flowing a process gas parallel to the surface of a substrate positioned on a support, and thermally decomposing the process gas to deposit a material from the gas onto the substrate surface. However, the material deposited on the surface of the substrate is often non-uniform in thickness, and therefore, negatively affects the performance of the final manufactured device.

Therefore, a need exists for improved process chamber components and related methods that facilitate depositing a material that is more uniform in thickness.

### SUMMARY

The present disclosure relates to an auxiliary flow plate for process kits and semiconductor processing chambers, and related methods and flow guides, to facilitate deposition process adjustability. In one or more embodiments, a chamber kit includes a liner, a first plate, and a second plate. The liner includes an inner face, a first ledge disposed along the inner face, and a second ledge disposed along the inner face. The second ledge is spaced from the first ledge along the inner face. The first plate is sized and shaped to be disposed within the liner on the first ledge. The second plate is sized and shaped to be disposed within the liner on the second ledge.

In one or more embodiments, a processing chamber includes a chamber body, one or more windows disposed within the chamber body, a liner disposed within the chamber body, a first plate disposed within the liner, and a second plate disposed within the liner and spaced from the first plate. The second plate includes a plurality of flow openings. The processing chamber also includes a substrate support disposed within the chamber body. The substrate support at least partially defines a process volume between the first plate and the substrate support.

In one or more embodiments, a method for substrate processing includes heating a substrate positioned on a substrate support, flowing a first gas over a substrate in a process volume to deposit a material on the substrate, flowing a second gas between a first plate and a second plate, and flowing the second gas to the process volume through a plurality of flow openings formed in the first plate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a partial schematic side cross-sectional view of a processing chamber, according to one or more embodiments.

FIG. 2A is a schematic enlarged view of the processing chamber shown in FIG. 1, according to one or more embodiments.

FIG. 2B is a schematic enlarged view of the processing chamber shown in FIG. 1, according to one or more embodiments.

FIG. 3 is a partial schematic perspective view of the first plate shown in FIG. 1, according to one or more embodiments.

FIG. 4 is a schematic partial top view of the flow of the second gas into the processing chamber shown in FIGS. 1 and 2, according to one or more embodiments.

FIGS. 5 and 6 are schematic partial side cross-sectional views of first plate shown in FIG. 1 in a processing chamber, according to one or more embodiments.

FIG. 7 is a is a schematic partial side cross-sectional view of first plate shown in FIG. 5 in a tilted position, according to one or more embodiments

FIG. 8 is a schematic partial side cross-sectional view of first plate shown in FIG. 5 in the tilted position, according to one or more embodiments.

FIG. 9 is a schematic block diagram view of a method of substrate processing, according to one or more embodiments.

FIG. 10 illustrates schematically a deposition map, according to one or more embodiments.

FIG. 11 illustrates schematically a deposition map 1100, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to an auxiliary flow plate for process kits and semiconductor processing chambers, and related methods. In one or more embodiments, the auxiliary flow plate is part of a dual-plate assembly disposed above a process volume.

A process chamber including an isolation plate can improve gas flow adjustability. The substrate lift position can be utilized to provide small range fine adjustability. Additional adjustability of isolation plate angle and/or isolation plate height can improve the gas speed for deposition uniformity and gas utilization. Increasing the space between the isolation plate and the substrate may decrease the gas speed, which can result in increased deposition on the substrate. Decreasing the space between the isolation plate and the substrate may increase the gas speed, which can result in decreased deposition on the substrate. As such, the space can be adjusted to adjust a deposition uniformity. A smaller gap between the isolation plate and the substrate support may be utilized during chamber cleaning operations, for example, to decrease chamber clean time. A larger gap may be utilized during high temperature substrate deposition operations, for example, to reduce window coating, extending time between cleaning processes. The present disclosure also contemplates that the smaller gap can be used during deposition operations and/or the larger gap may be used during cleaning operations. Operations may use a variety of gaps and isolation plate angles.

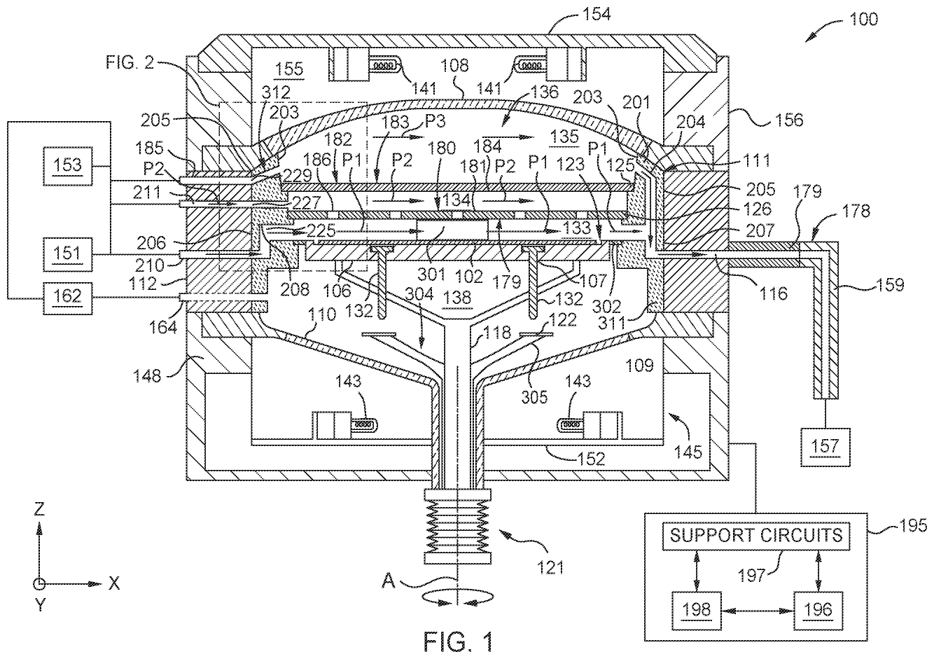

FIG. 1 is a partial schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface of the substrate 102. The processing chamber 100 is shown in a processing condition in FIG. 1.

The processing chamber 100 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, one or more windows (e.g., an upper window 108 (such as an upper dome) and a lower window 110 (such as a lower dome)), a plurality of upper heat sources 141, and a plurality of lower heat sources 143. The present disclosure contemplates that each of the heat sources described herein can include one or more of: lamp(s), resistive heater(s), light emitting diode(s) (LEDs), and/or laser(s). The present disclosure contemplates that other heat sources can be used.

The substrate support 106 is disposed between the upper window 108 and the lower window 110. The substrate support 106 includes a support face 123 that supports the substrate 102. The plurality of upper heat sources 141 are disposed between the upper window and a lid 154. The plurality of upper heat sources 141 form a portion of the upper heat source module 155. The lid 154 may include a plurality of sensors (not shown) disposed therein or thereon for measuring the temperature within the processing chamber 100. The plurality of lower heat sources 143 are disposed in a lower cavity 109. The plurality of lower heat sources 143 are disposed between the lower window 110 and a floor 152. The plurality of lower heat sources 143 form a portion of a lower heat source module 145. In one or more embodiments, the upper window 108 is an upper dome and is formed of an energy transmissive material, such as transparent quartz. In one or more embodiments, the lower window 110 is a lower dome and is formed of an energy transmissive material, such as transparent quartz. In one or more embodiments, the upper window 108 and the lower window 110 are transparent quartz domes. A pre-heat ring 302 is disposed outwardly of the substrate support 106.

The pre-heat ring 302 is supported on a ledge of the lower section 311 (described below). A lift frame 304 includes a plurality of arms 305 that each include a lift pin stop 122 on which at least one of the lift pins 132 can rest when the substrate support 106 is lowered (e.g., lowered from a process position to a transfer position).

The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin holes 107 disposed therein. The lift pin holes 107 are sized to accommodate a respective lift pin 132 for lifting of the substrate 102 from the substrate support 106 either before or after a deposition process is performed.

The process chamber 100 also includes a liner 111. The liner 111 is disposed between the upper window 108 and the lower window 110. The liner 111 includes an upper section 312 and a lower section 311. The liner 111 is disposed radially outward of the substrate support 106. In one or more embodiments, the liner 111 includes a single body with multiple openings (e.g., holes and/or recesses) formed in and through the single body. In such an embodiment, the upper section 312 and the lower section 311 can be integrally formed as the single body. In one or more embodiments, the liner 111 includes multiple bodies stacked on each other. In such an embodiment, the openings of the liner 111 can include holes and/or interfacing recesses of the multiple bodies. In such an embodiment, the lower section 311 can include a first body and the upper section 312 can include a second body above the first body. In one or more embodiments, the upper section 312 can include a second body and a third body disposed on the second body.

The process chamber 100 includes an interior 136. The interior 136 includes a process volume 133, a first volume 134, a second volume 135, and a purge volume 138. The volumes 133, 134, 135, and 138 are described below.

The upper section 312 includes an inner face 203, a second ledge 125 disposed along the inner face 203, and a first ledge 126 disposed along the inner face 203. The first ledge 126 is disposed away from the second ledge 125.

The first ledge 126 is disposed between the second ledge 125 and the substrate support 106. The second ledge 125 is disposed along the inner face 203 of the upper section 312.

The process chamber 100 also includes a first plate 180 and a second plate 182. The first plate 180 is disposed between the first volume 134 and the process volume 133. The first plate 180 is sized and shaped to be placed within the liner 111 on a first ledge 126. The first plate 180 has a top face 181 and a bottom face 179 opposing the top face 181. The bottom face 179 faces the substrate support 106. The first plate 180 is formed of an energy transmissive material, such as quartz (e.g., transparent quartz).

The second plate 182 is sized and shaped to be placed within the liner 111 on the second ledge 125.

The second plate 182 has a top face 183 and a bottom face 184 opposing the top face 183. The bottom face 184 is disposed towards the substrate support 106. The second plate 182 is formed of an energy transmissive material, such as quartz (e.g., transparent quartz). In one or more embodiments, and as shown in FIG. 1, the second plate 182 includes a solid body having a solid cross section across an outer dimension (such as an outer diameter) of the second plate 182.

In one or more embodiments, the upper section 312, the lower section 311, the first plate 180, and/or the second plate 182 are part of a chamber kit to be implemented into process chambers (such as the process chamber 100) for use in semiconductor manufacturing.

The upper section 312 includes an annular portion 201. The annular portion 201 at least partially defines the second volume 135, the first volume 134, and the process volume 133.

The upper section 312 includes one or more supply openings 225, 227, 229 extending to an inner face 203 of the annular portion 201 on a first side of the upper section 312, and one or more outlet openings 204 extending to the inner face 203 of the annular portion 201 on a second side of the upper section 312.

The supply openings 225, 227, 229 and the outlet openings 204 flow fluids into and out of the volumes 133, 134, 135. In one or more embodiments, the second volume 135 is filled with an inert gas. It is contemplated that a portion or all of inner face 203 may be curved to engage with the first plate 180 as the first plate 180 can be disposed at an angle.

The one or more openings 225, 227, 229 extend from an outer surface 205 of the annular portion 201 of the upper section 312 to the inner face 203. The one or more outlet openings 204 extend into the inner face 203 and between the lower section 311 and the upper section 312. In one or more embodiments, the one or more outlet openings 204 extend to a lower face 208 of the upper section 312. In one or more embodiments, the upper section 312 includes an extension 206 disposed outwardly of a lower face 208 of the upper section 312. At least part of the annular portion 201 of the upper section 312 is aligned with the extension 206.

The first plate 180 is in the shape of a disc, and the annular portion 201 is in the shape of a ring. It is contemplated that the first plate 180 and/or the annular portion 201 can be in the shape of a rectangle, or other geometric shapes.

The first plate 180 has a thickness between the top face 181 and the bottom face 179. The thickness of the first plate 180 is within a range of about 1 millimeter to about 5 millimeters.

The second plate 182 is in the shape of a disc. It is contemplated, however, that the second plate 182 can be in the shape of a rectangle, or other geometric shapes. The second plate 182 at least partially fluidly isolates the second volume 135 from the first volume 134 and the process volume 133. In one or more embodiments, the second plate 182 fluidly isolates the second volume 135 of the interior 136 from the first volume 134 of the interior 136.

The second plate 182 has a thickness between the top face 183 and the bottom face 184. The thickness of the second plate 182 is within a range of about 1 millimeter to about 5 millimeters.

The flow module 112 (which can be at least part of one or more sidewalls of the processing chamber 100) includes one or more first inlet openings 210 in fluid communication with the process volume 133 of the interior 136. The flow module 112 includes one or more first inlet openings 210 in fluid communication with the process volume 133 through one or more first supply openings 225 of the liner 111, and one or more second inlet openings 211 in fluid communication with the first volume 134 of the interior 136 through one or more second supply openings 227 of the liner 111. The flow module 112 includes one or more third inlet openings 185 in fluid communication with the second volume 135 of the interior 136 through one or more third supply openings 225 of the liner 111. In one or more embodiments, the lower section 311 includes a first body, the upper section 312 includes a second body above the first body, and the one or more first supply openings 225 include recesses formed in the first body and/or the second body. In one or more embodiments, the upper section 312 includes the second body and a third body above the second body, and the one or more second supply openings 227 or the one or more third supply openings 229 include recesses formed in the second body and/or the third body.

The one or more second inlet openings 211 are in fluid communication with the one or more second supply openings 227 of the upper section 312. The one or more second inlet openings 211 are fluidly connected to one or more process gas sources 151 and one or more cleaning gas sources 153.

The one or more first inlet openings are fluidly connected to one or more process gas sources 151 and one or more cleaning gas sources 153.

One or more purge gas inlets 164 are fluidly connected to one or more purge gas sources 162.

The one or more third inlet openings 185 are fluidly connected to one or more purge gas sources 162.

The one or more gas exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂).

One or more cleaning gases supplied using the one or more cleaning gas sources 153 can include one or more of hydrogen and/or chlorine. In one or more embodiments, the one or more process gases include silicon phosphide (SiP) and/or phosphine (PH3), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157 with an exhaust line 159. The exhaust system 178 can assist in the controlled deposition of a layer on the substrate 102. The exhaust system 178 is disposed on an opposite side of the processing chamber 100 relative to the flow module 112.

In one or more embodiments, as shown in FIG. 1, the one or more second supply openings 227 are oriented in a horizontal orientation and the one or more outlet openings 204 are oriented in a partially angled orientation, a partially vertical orientation, and a partially horizontal orientation. In one or more embodiments, the one or more first supply openings 225 are oriented in a partially horizontal orientation and a partially vertical orientation. In one or more embodiments, the one or more third supply openings 225 are oriented in an angled orientation. The present disclosure contemplates that the supply openings 225, 227, 229 and/or outlet openings 204 can be oriented in horizontal orientations, oriented in angled orientations, and/or can include one or more turns (such as the turns shown for the one or more first supply openings 225 and the one or more outlet openings 204).

During a deposition operation (e.g., an epitaxial growth operation), one or more process gases P1 flow through the one or more first inlet openings 210, through the one or more first supply openings 225, and into the process volume 133 of the interior 136 to flow over the substrate 102. During the deposition operation, one or more second gases P2 flow through the one or more second inlet openings 211, through the one or more second supply openings 227 of the upper section 312, and into the first volume 134 of the interior 136. The one or more second gases P2 flow through the first plate 180 and flow into the process volume 133 by flow openings 186 formed in the first plate 180. One or more third gases P3 flow through the one or more third inlet openings 185, through the one or more third supply openings 225, and into the second volume 135. The one or more third gases P3 flow over the second plate 182.

The second gases P2 may apply additional pressure to the process gases P1 and mix with the one or more process gases P1. The one or more process gases P1 and the one or second gases P2 are exhausted through gaps between the upper section 312 and the lower section 311, through the one or more outlet openings 204, and through the one or more gas exhaust outlets 116. The one or more third gases P3 are exhausted through the one or more outlet openings 204, and through the same one or more gas exhaust outlets 116 as the one or more process gases P1. The present disclosure contemplates that that the one or second gases P2 and/or the one or more third gases P3 can be separately exhausted through one or more second gas exhaust outlets and/or one or more third gas exhaust outlets that are separate from the one or more gas exhaust outlets 116.

The one or more second gases P2 may include inert purge gas, process gas, cleaning gas, or any combination thereof. The one or more third gases P3 may include inert purge gas, process gas, cleaning gas, or any combination thereof. In one or more embodiments, the one or more process gases P1 include a deposition gas, the one or more second gases P2 include a deposition gas and/or a purge gas, and the one or more third gases P3 include a purge gas.

The present disclosure also contemplates that one or more purge gases can be supplied to the purge volume 138 (through the plurality of purge gas inlets 164) during the deposition operation, and exhausted from the purge volume 138. The second volume 135 may be maintained at a first pressure higher than a second pressure in the first volume 134 and a third pressure in the process volume 133 to ensure that gases do not travel up through the outlet openings 204 into the second volume 135 from the process volume 133.

The flow of gases in the purge volume 138 and the second volume 135 during the deposition operation, a purge operation, and/or the cleaning operation facilitates reduced or eliminated backflow of gases at the one or more outlet openings 204 (e.g., backflow from the one or more outlet openings 204 into the process volume 133) and the one or more gas exhaust outlets 116 (e.g., backflow from the gaps into the purge volume 138).

In one or more embodiments, the process chamber 100 may also include a height adjustment system 301. The height adjustment system 301 is disposed above the substrate support 106 and can be used to adjust the distance between the bottom face 179 of the first plate 180 and the substrate support 106. The height adjustment system 301 is discussed in more detail below.

As shown, a controller 195 is in communication with the processing chamber 100 and is used to control processes and methods, such as at least some of the operations of the methods described herein.

The controller 195 is configured to receive data or input as sensor readings from a plurality of sensors. The sensors can include, for example: sensors that monitor growth of layer(s) on the substrate 102; sensors that monitor growth or residue on inner surfaces of chamber components of the processing chamber 100 (such as inner surfaces of the upper window 108 and/or the liner sections 311, 312); sensors that monitor gas flow of the one or more gases P1, P2, P3; and/or sensors that monitor temperatures of the substrate 102, the substrate support 106, the upper window 108, the lower window 110, the upper section 312, and/or the lower section 311. The controller 195 is equipped with or in communication with a system model of the processing chamber 100. The system model includes a heating model, a deposition model, a coating model, a rotational position model, and/or a gas flow model. The system model is a program configured to estimate parameters (such as a gas flow rate, an angular position of the first plate 180, a height of the first plate 180, a center-to-edge uniformity profile, a gas pressure, a processing temperature, a rotational position of component(s), a heating profile, a coating condition, and/or a cleaning condition) within the processing chamber 100 throughout a deposition operation and/or a cleaning operation. The controller 195 is further configured to store readings and calculations. The readings and calculations include previous sensor readings, such as any previous sensor readings within the processing chamber 100. The readings and calculations further include the stored calculated values from after the sensor readings are measured by the controller 195 and run through the system model. Therefore, the controller 195 is configured to both retrieve stored readings and calculations as well as save readings and calculations for future use. Maintaining previous readings and calculations enables the controller 195 to adjust the system model over time to reflect a more accurate version of the processing chamber 100.

The controller 195 can monitor, estimate an optimized parameter, adjust the angular position of the plate 321 and/or the height of the plate 321, detect a coating condition for the upper window 108, generate an alert on a display, halt a deposition operation, initiate a chamber downtime period, delay a subsequent iteration of the deposition operation, initiate a cleaning operation, detect a cleaning condition for the upper window 108, halt the cleaning operation, adjust a heating power, and/or otherwise adjust the process recipe.

The controller 195 includes a central processing unit (CPU) 198 (e.g., a processor), a memory 196 containing instructions, and support circuits 197 for the CPU 198. The controller 195 controls various items directly, or via other computers and/or controllers. In one or more embodiments, the controller 195 is communicatively coupled to dedicated controllers, and the controller 195 functions as a central controller.

The controller 195 is of any form of a general-purpose computer processor that is used in an industrial setting for controlling various substrate processing chambers and equipment, and sub-processors thereon or therein. The memory 196, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 197 of the controller 195 are coupled to the CPU 198 for supporting the CPU 198. The support circuits 197 include cache, power supplies, clock circuits, input/output circuitry and subsystems, and the like.

Operational parameters (e.g., a center-to-edge profile, an angular position of the first plate 180, a height of the first plate 180, the coating condition, a pressure for gases P1, P2, P3, a processing temperature, a heating profile, a flow rate for gases P1, P2, P3, and/or a rotational position of the substrate support 106) and operations are stored in the memory 196 as a software routine that is executed or invoked to turn the controller 195 into a specific purpose controller to control the operations of the various chambers/modules described herein. The controller 195 is configured to conduct any of the operations described herein. The instructions stored on the memory, when executed, cause one or more of operations of a method (such as the method 900 described below) to be conducted in relation to the processing chamber 100. The controller 195 and the processing chamber 100 are at least part of a system for processing substrates.

The various operations described herein (such as the operations of the method 900) can be conducted automatically using the controller 195, or can be conducted automatically or manually with certain operations conducted by a user.

In one or more embodiments, the controller 195 includes a mass storage device, an input control unit, and a display unit. The controller 195 monitors the temperature of the substrate 102, the temperature of the substrate support 106, the temperature of the upper window 108, the process gas flow, and/or the purge gas flow. In one or more embodiments, the controller 195 includes multiple controllers 195, such that the stored readings and calculations and the system model are stored within a separate controller from the controller 195 which controls the operations of the processing chamber 100. In one or more embodiments, all of the system model and the stored readings and calculations are saved within the controller 195.

The controller 195 is configured to control the sensor devices, the deposition, the cleaning, the rotational position, the heating, and gas flow through the processing chamber 100 by providing an output to the controls for the heat sources, the gas flow, and the motion assembly 121. The controls include controls for the sensor devices, the upper heat sources 141, the lower heat sources 143, the process gas source 151, the purge gas source 162, the motion assembly 121, and the exhaust pump 157.

The controller 195 is configured to adjust the output to the controls based on the sensor readings, the system model, and the stored readings and calculations. The controller 195 includes embedded software and a compensation algorithm to calibrate measurements. The controller 195 can include one or more machine learning algorithms and/or artificial intelligence algorithms that estimate optimized parameters for the deposition operations and/or the cleaning operations (such as for adjusting a deposition operation (e.g. the process recipe), halting the deposition operation, initiating a chamber downtime period, delaying a subsequent iteration of the deposition operation, initiating a cleaning operation, halting the cleaning operation, adjusting a heating power, and/or adjusting the cleaning operation). The optimized parameter can include, for example, a center-to-edge profile for the substrate 102 (which facilitates uniformity) with respect to temperature, gas flow rate, and/or deposition thickness.

The one or more machine learning algorithms and/or artificial intelligence algorithms may implement, adjust, and/or refine one or more algorithms, inputs, outputs or variables described above. Additionally or alternatively, the one or more machine learning algorithms and/or artificial intelligence algorithms may rank or prioritize certain aspects of adjustments of the process chamber 100 and/or the method 900 relative to other aspects of the process chamber 100 and/or the method 900. The one or more machine learning algorithms and/or artificial intelligence algorithms may account for other changes within the processing systems such as hardware replacement and/or degradation.

In one or more embodiments, the one or more machine learning algorithms and/or artificial intelligence algorithms account for upstream or downstream changes that may occur in the processing system due to variable changes of the process chamber 100 and/or the method 900. For example, if variable “A” is adjusted to cause a change in aspect “B” of the process, and such an adjustment unintentionally causes a change in aspect “C” of the process, then the one or more machine learning algorithms and/or artificial intelligence algorithms may take such a change of aspect “C” into account. In such an embodiment, the one or more machine learning algorithms and/or artificial intelligence algorithms embody predictive aspects related to implementing the process chamber 100 and/or the method 900. The predictive aspects can be utilized to preemptively mitigate unintended changes within a processing system.

The one or more machine learning algorithms and/or artificial intelligence algorithms can use, for example, a regression model (such as a linear regression model) or a clustering technique to estimate optimized parameters. The algorithm can be unsupervised or supervised. The one or more machine learning algorithms and/or artificial intelligence algorithms can optimize, for example, a heating power applied to the heat sources 141, 143, the angular position of the first plate 180, and/or the height of the first plate 180. The one or more machine learning algorithms and/or artificial intelligence algorithms can optimize, for example, a size and/or a shape of the process volume 133 and/or the first volume 134 using the angular position and/or the height of the first plate 180.

The one or more machine learning algorithms and/or artificial intelligence algorithms can optimize, for example, a center-to-edge gas concentration profile across a substrate 102 during deposition operations. The center-to-edge gas concentration profile can be pre-generated using simulation operations, and the one or more machine learning algorithms and/or artificial intelligence algorithms can use real-time collected data to adjust the center-to-edge gas concentration profile. The center-to-edge concentration profile is affected, for example, by the size and/or the shape of the process volume 133.

In one or more embodiments, the controller 195 automatically conducts one or more operations described herein without the use of one or more machine learning algorithms or artificial intelligence algorithms. In one or more embodiments, the controller 195 compares measurements (such as of gas flow rate(s)) and/or deposition thickness to data in a look-up table and/or a library to determine if adjustment(s) can be used to facilitate a center-to-edge profile. The controller 195 can store measurements as data in the look-up table and/or the library.

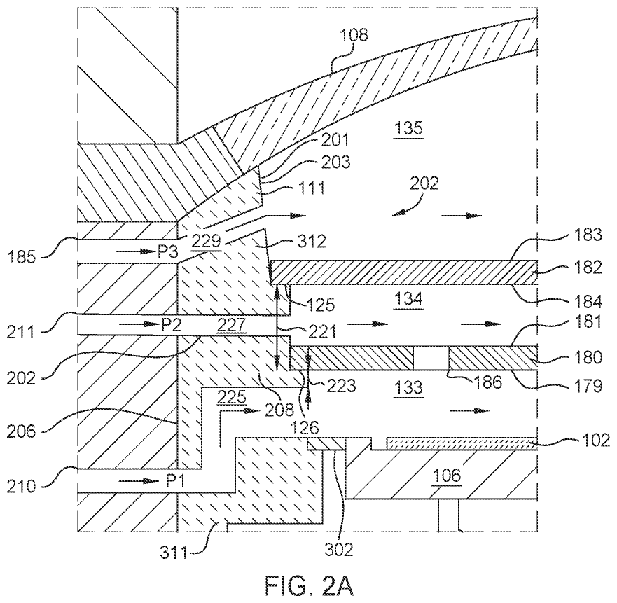

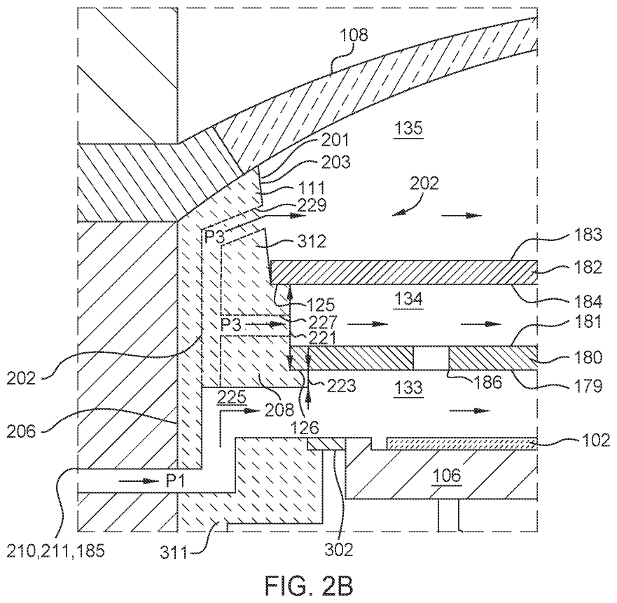

FIG. 2A is a schematic enlarged view of the processing chamber 100 shown in FIG. 1, according to one or more embodiments. The processing chamber 100 is shown in a processing condition in FIG. 2A.

During a cleaning or deposition operation, one or more process gases P1 flow through the one or more first inlet openings 210, and flow into the process volume 133. During the operation, one or more second gases P2 flow through the one or more second inlet openings 211, through the one or more second supply openings 227 of the upper section 312, and into the first volume 134. The flowing of the one or second gases P2 through first volume 134 can enhance deposition uniformity, for example.

The processing chamber 100 facilitates separating the gases P1, P2, provided to the first volume 134 and process volume 133 from gases P3 provided to the second volume 135. By allowing the second gas P2 to join the process gas P1 and allowing the second gas P2 to pass through the flow openings 186, the process chamber 100 can be adjusted to specific process parameters, thereby enhancing the deposition uniformity. Additionally, one or more purge gases and/or one or more cleaning gases can be separately provided to the first volume 134 and process volume 133 to facilitate reduced contamination of the upper window 108, the second plate 182, and the first plate 180. By further separating process gases P1 from the upper window 108, the upper window 108 operational lifespan will be extended.

As shown in FIGS. 1 and 2, the one or more second inlet openings 211 can be aligned above the one or more first inlet openings 210.

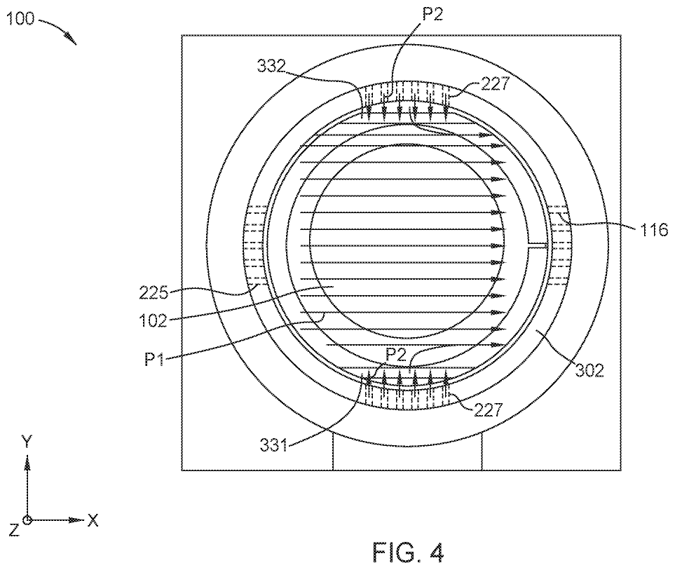

The one or more second inlet openings 211 can be angularly offset from the one or more first inlet openings 210, and the one or more first supply openings 225 of the upper section 312 can be angularly offset from the one or more first supply openings 225 between the upper section 312 and the lower section 311. This offset is discussed below at FIG. 4.

As shown in FIG. 2A, the second plate 182 has a diameter larger than a diameter of the first plate 180. In one or more embodiments, the second plate 182 includes an outer diameter larger than an outer diameter of the first plate 180. The first ledge 126 is disposed away from the second ledge 125. The first ledge 126 is disposed a first distance 221 away from the second ledge 125. The first distance 221 is within a range of about 1 millimeters to about 11 millimeters, such as about 1 millimeter to about 10 millimeters, or about 3 millimeter to about 10 millimeters.

The first ledge 126 is disposed a second distance 223 away from the lower face 208 of the upper liner 111. The second distance 223 is within a range of about 1 millimeter to about 5 millimeters, such as about 2 millimeters to about 5 millimeters.

In one or more embodiments, the lower face 208 of the upper section 312 is the face between the first ledge 126 and the substrate support 106. The lower face 208 defines a lower boundary of the upper section 312. In one or more embodiments, the lower face 208 is a process face boundary of the upper section 312 nearest the substrate support 106. In other words, the process face is disposed facing the substrate support 106.

The openings 225, 227, 229 include one or more first supply openings 225, one or more second supply openings 227, and one or more third supply openings 229.

As discussed, the one or more first supply openings 225 provide the process gas P1 to the process volume 133. For example, the one or more first supply openings 225 may provide process gas P1 to the process volume 133 at a process flow rate and a process pressure. The process pressure of the process volume 133 is within a range of about 1 torr to about 300 torr, such as about 10 Torr to about 20 Torr. In one or more embodiments, the one or more first supply openings 225 are passages through the gaps between the upper section 312 and the lower section 311. In one or more embodiments, the first supply openings 225 are first supply ports that can form a flow path created by a recess in the upper section 312 and/or a recess in the lower section 311.

The one or more second supply openings 227 provide the second gas P2 to the first volume 134. For example, the one or more second supply openings 227 may provide the second gas P2 to the first volume 134 at a first flow rate and a first pressure. The first pressure of the first volume 134 is within a range of about 1% to about 30% higher than the process pressure of the process volume 133, such as about 1% to about 5% higher, or about 10% to about 30% higher. In one or more embodiments, the first pressure is within a range of about 1% to about 20% higher than the process pressure. In one or more embodiments, the first pressure within a range of about 5 Torr to about 10 Torr higher than the process pressure. In one or more embodiments, the first pressure within a range of about 2 Torr to about 3 Torr higher than the process pressure. The first flow rate is within range of about 1% and about 20% higher than a flow rate of process gas P1. In one or more embodiments, the one or more second supply openings 227 are passages (e.g., holes) through the upper section 312. While shown as parallel and/or aligned in FIGS. 1 and 2, the first supply openings 225 may be disposed perpendicular to the one or more second supply openings 227. The one or more second supply openings 227 are disposed between the first ledge 126 and the second ledge 125. In one or more embodiments, the second supply openings 227 are second supply ports that can form a flow path created by a recess in the upper section 312.

The one or more third supply openings 229 provide a third gas P3 to the second volume 135. For example, the one or more third supply openings 229 may provide a purge gas to the second volume 135 at a second flow rate and a second pressure. In one or more embodiments, the second pressure is about equal to the process pressure of the process volume 133. In one or more embodiments, the second pressure of the second volume 135 is within a range of about equal to the second pressure of the first volume 134 to about 20% higher than the second pressure. The second flow rate is within a range of about 10% of the flow rate of the process gas P1 to about equal to the flow rate of the process gas P1. In one or more embodiments, the second flow rate is within a range of about 5% of the flow rate of the process gas P1 to about 15% of the flow rate of the process gas P1, such as about 10% of the flow rate of the process gas P1. The one or more third supply openings 229 are passages through the upper section 312. While shown as parallel and/or aligned in FIGS. 1 and 2, the first supply openings 225 may be disposed perpendicular to the one or more third supply openings 229. In one or more embodiments, the third supply openings 229 are third supply ports that can form a flow path created by a recess in the upper section 312.

In the implementation shown in FIG. 2A, the bottom face 179 of the first plate 180 is disposed above a lowermost end of the upper section 312. In one or more embodiments, the bottom face 179 of the first plate 180 is aligned with the lower face 208 of the upper section 312. The present disclosure contemplates that the lowermost end of the upper section 312 can be part of the lower face 208.

FIG. 2B is a schematic enlarged view of the processing chamber 100 shown in FIG. 1, according to one or more embodiments. The implementation shown in FIG. 2B is similar to the implementation shown in FIG. 2A. In the implementation shown in FIG. 2B, the inlet openings 210, 211, 285 are aligned with each other in a horizontal plane. The inlet openings 210, 211, 285 can be offset (e.g., can alternate) with respect to each other along a circumferential direction of the liner 111. The inlet openings 210, 211, 285 can be in fluid communication with each other or fluidly isolated from each other. In the implementation shown in FIG. 2B, the one or more first supply openings 225, the one or more second supply openings 227, and the one or more third supply openings 229 are offset with respect to each other along a circumferential direction of the liner 111. The supply openings 225, 227, 229 can alternate with respect to each other along the circumferential direction of the liner 111.

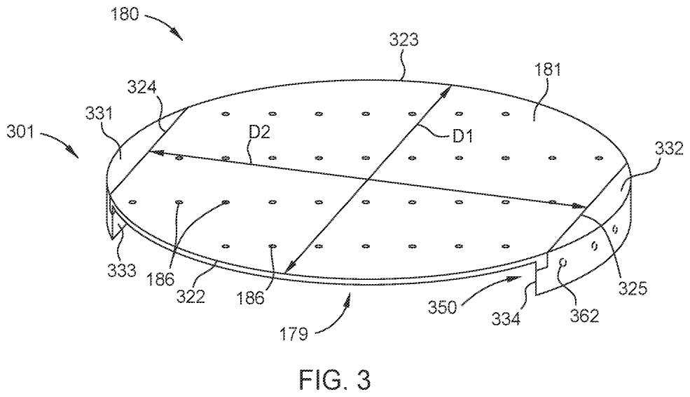

FIG. 3 is a schematic partial perspective view of the first plate 180 shown in FIG. 1, according to one or more embodiments. The height adjustment system 301 includes a first block 331, and a parallel block 332. The first block 331 and the second block 332 are disposed opposite one another and support the first plate 180. The first and second blocks 331, 332 can be oriented parallel to each other. In one or more embodiments, the first and second blocks 331, 332 are coupled to the first plate 180. The height adjustment system 301 and the first plate 180 have a circular shape, but other geometric configurations are contemplated.

As shown in FIG. 3, the first plate 180 has a first side 322 (adjacent the one or more first inlet openings 210 and first supply openings 225 in FIGS. 1 and 2) and a second side 323 opposing the first side 322 along a first direction D1. Each of the first side 322 and the second side 323 is arcuate.

In one or more embodiments, the direction D1 is parallel to the direction of gas flow in the process chamber 100 of FIG. 1 in order to guide process gas P1 within the rectangular flow opening 350 defined between a planar inner surface 333 of the first block 331 and a planar inner surface 334 of the second block 332.

The first block 331 extends outwardly from and couples to a third side 324 of the first plate 180, and the second block 332 extends outwardly from and couples to a fourth side 325 of the first plate 180. The third side 324 is opposite the fourth side 325 along a direction D2, which is perpendicular to direction D1. The third side 324 and the fourth side 325 are linear, as are surfaces of the first block 331 and the second block 332 which mate with the third side 324 and the fourth side 325 of the first plate 180. In one or more embodiments, the process gas P1 (FIGS. 2A and 2B) flows along the direction D1 and at least part of the second gas P2 (FIGS. 2A and 2B) flows along the direction D2.

It is contemplated that the first block 331 and the second block 332 may be omitted from the height adjustment system 301. In one or more embodiments where the blocks 331 and 332 are omitted, the first plate 180 can be supported by the first ledge 126 of the upper section 312 and the first plate 180 may be secured in the interior of the processing chamber via another attachment mechanism. The first plate 180 is shown as semi-discal in shape in FIG. 3. As described above, the present disclosure contemplates that the first plate 180 can be discal in shape.

It is contemplated that in embodiments with the first block 331 and second block 332, the size of the blocks may be varied to increase or decrease the processing volume 133. It is also contemplated that the first block 331 and second block 332 may include actuating supports configured to mechanically move the first plate 180 up and down. It is also contemplated that the first block 331 and second block 332 may have different heights to angle the first plate 180 within the process chamber 100 such that the first plate 180 is not parallel with the support face 123 (FIG. 1) of the substrate support 106.

During processing, one or more process gases (such as process gas P1 of FIG. 1) flow through the rectangular flow opening 350 when flowing through the process volume 133 and over the substrate 102. The rectangular flow opening 350 facilitates adjustability of process gases, purge gases, and/or cleaning gases (such as pressure and flow rate), to facilitate process uniformity and deposition uniformity while providing a path for second gases P2 to the process volume 133 from the first volume 134. As an example, the rectangular flow opening 350 facilitates using high pressures and low flow rates for the process gases and the cleaning gases. The rectangular flow opening 350 also facilitates mitigation of the effects that rotation of the substrate 102 has on process uniformity and film thickness uniformity during a deposition operation. As an example, the rectangular flow opening mitigates or removes the effects of gas vortex.

In FIG. 3, the first plate 180 includes the plurality of flow openings 186 formed therethrough. The flow openings 186 are sized, spaced (e.g., for hole density) and angled to allow gas (e.g., second gas P2 of FIGS. 1 and 2) to flow from the top face 181 of the first plate 180 to the bottom face 179 during processing. It is contemplated that the flow openings 186 may be arranged through first plate 180 by a nodal analysis, or that the flow openings 186 may have an increasing size or density along a direction (such as D1 or D2). The flow openings 186 may be uniform in size, or the sizes may be non-uniform. In one or more embodiments, the flow openings 186 are through holes extending through the first plate 180 but other openings such as recesses could be used. The flow openings 186 can be parallel to the thickness of the first plate 180 or can be oriented at an angle relative to the thickness of the first plate 180. In one or more embodiments, the spacing between the flow openings 186 may be uniform. In one or more embodiments, the flow openings 186 may be clustered in specified areas of the first plate 180. In one or more embodiments, the first plate 180 may have many small flow openings 186 covering the entire plate to keep the first plate 180 clean. The first plate 180 may have several larger flow openings 186 strategically located to increase deposition uniformity on the substrate 102. For example, a first flow opening of a plurality of flow openings 186 can be larger than a second flow opening of the plurality of flow openings 186. At least one flow opening of the plurality of flow openings 186 has a diameter within a range of about 0.1 millimeters to about 2 millimeters, for example, about 0.3 millimeters to about 0.5 millimeters. At least one flow opening of the plurality of flow openings 186 may have a circular shape or a non-circular, for example rectangular or triangular shape. In one or more embodiments, the first plate 180 is an auxiliary flow plate that provides the second gas P2 to the process volume 133, in addition to the flow of the one or more process gases P1. In one or more embodiments, the first plate 180 is a gas distribution plate, such as a showerhead.

Facing the top of the first plate 180, the flow openings 186 may be circular, as shown in FIG. 3. It is also contemplated that the flow openings 186 may be slits or any other regular or irregular shape, such as in the shape of an elongated slot. Within the first plate 180, the flow openings 186 may form a right cylinder, an oblique cylinder, a frustum, or any other regular or irregular three-dimensional shape with respect to a plane of the first plate 180. It is contemplated that the flow openings 186 form right angles with the outer face 345 of the first plate 180. It is contemplated that the flow openings 186 may tilt towards the process gas P1 flow direction.

During processing, second gas P2 flows through the flow openings 186 of the first plate 180 from the first volume 134 to the process volume 133 (see FIG. 1). The second gas P2 can form a relatively thin gas curtain along the bottom face 179 of the first plate 180. The gas curtain reduces material deposition on the first plate 180, extending time between cleaning operations. In addition, the gas curtain allows a substrate to be positioned closer to the first plate 180 during processing, thus reducing the processing volume 133 and the amount of processing gas utilized. In addition, the plurality of flow openings 186 may further increase the deposition rate of a process while maintaining uniformity of the deposited layer.

In one or more embodiments, the top face 181 includes a topography. The topography may be a specific arrangement of flow openings 186 and surface features chosen to enhance deposition uniformity. For example, the top face 181 may be disposed at an angle to a bottom face 179 of the first plate 180.

In one or more embodiments, the first block 331 and the second block 332 include a plurality of block flow openings 362. The block flow openings 362 further aid the dispersion of process gas P1 and second gas P2 (FIGS. 2A and 2B).

FIG. 4 is a schematic partial top view of the flow of the second gas into the processing chamber 100 shown in FIGS. 1 and 2, according to one or more embodiments. The first supply openings 225 allow flow of the one or more process gases P1 into the process chamber. The second supply openings 227 allow flow of the second gas P2 into the processing chamber 100. The flow openings 186 (FIGS. 2A and 2B) in the first plate 180 allow for at least a portion of the second gas P2 to flow from the first volume 134 (FIGS. 2A and 2B) of the process chamber into the process volume 133. The flow of the process gas P1 directs the flow of the second gas P2 towards the exhaust outlets 116 of the process chamber 100. The flowrate of the flow can be determined in part by the flow rate of the second gas P2 and the location, number, size, and shape of the flow openings 186 in the first plate 180.

As shown in FIG. 4, the one or more first supply openings 225 are aligned with the exhaust outlets 116 across the interior 136. The one or more second supply openings 227 are oriented about perpendicular to the exhaust outlets 116 from the top view shown in FIG. 4. The present disclosure contemplates that, in addition to or in place of the one or more second supply openings 227 shown in FIG. 4, one or more second supply openings 227 can be aligned above the one or more first supply openings 225 shown FIG. 4 to be aligned with the exhaust outlets 116 across the interior 136. The present disclosure contemplates that, in in addition to or in place of the one or more first supply openings 225 shown in FIG. 4, one or more first supply openings 225 can be aligned below the one or more second supply openings 227 shown in FIG. 4 to be oriented about perpendicular to the exhaust outlets 116 from the top view shown in FIG. 4. The present disclosure contemplates that the one or more third supply openings 229 (shown in FIGS. 1 and 2) can be aligned above the one or more first supply openings 225 shown in FIG. 4 to be aligned with the exhaust outlets 116 and/or can be aligned above the one or more second supply openings 227 to be oriented about perpendicular to the exhaust outlets 116.

Without being limited by theory, the flow of the second gas P2 and the third gas P3 reduces the potential for deposition on the first plate 180, the second plate 182, and the window 108. The second gas P2 can form a gas curtain adjacent the first plate 180 and/or dilute the process gas P1 concentration. Additionally or alternatively, the second gas P2 can mix with the process gas P1 and increase the process (e.g., deposition) concentration. The flow also can push the process gas flow P1 towards the substrate 102 (FIG. 1), increasing the gas speed delta between the peak speed and the speed at the substrate surface.

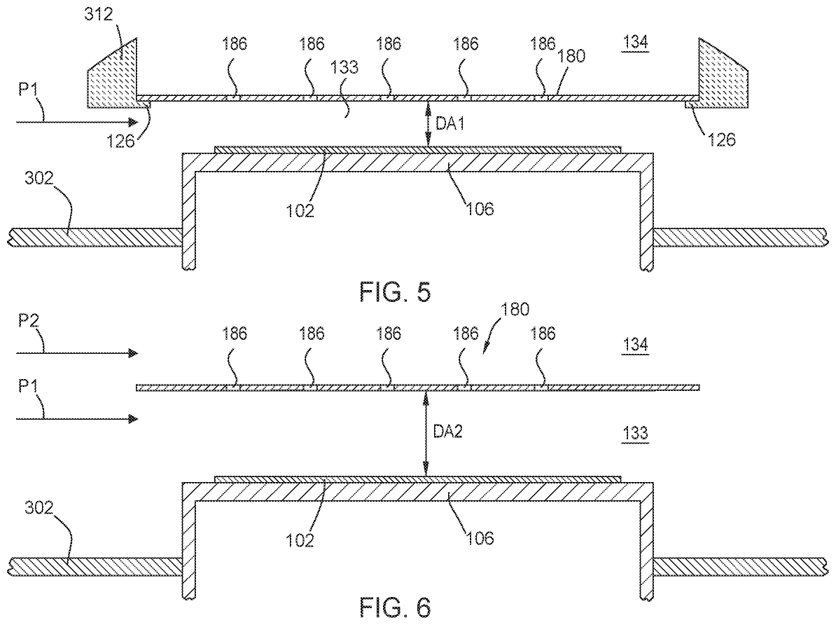

FIGS. 5 and 6 are schematic partial side cross-sectional views of first plate 180 shown in FIG. 1 in a processing chamber, according to one or more embodiments. Part of the upper section 312 is shown in FIG. 5 for visual clarity purposes. The upper section 312 is now shown in FIG. 6 for visual clarity purposes. As shown in FIG. 5, a distance DA1 between the first plate 180 and the substrate 102 (on another side) is lesser than the distance DA2 shown in FIG. 6. One or more of the substrate support 106 and/or the first plate 180 can be moved to adjust the distance D1 depending on the process parameters. For example, the distance DA1 can be adjusted to adjust a deposition uniformity on the substrate 102. The distance DA1 can be adjusted during processing operations and/or between iterations of processing operations. In one or more embodiments, the first plate 180 can remain on the first ledge 126 of the upper section 312 during adjustment of the distance DA1. In one or more embodiments, the first plate 180 can lift off to be at a gap from the one or more first ledge 126 during adjustment of the distance DA1. In one or more embodiments, the distance DA1 shown in FIG. 5 is within a range of 0.2 mm to 2.0 mm (such as 1.0 mm). The distance DA1 during process (e.g., deposition) operations can vary within a range of 0.2 mm to 5.0 mm (such as within a range of 1.0 mm to 5.0 mm). Other values are contemplated for the distance DA1 and the distance DA2.

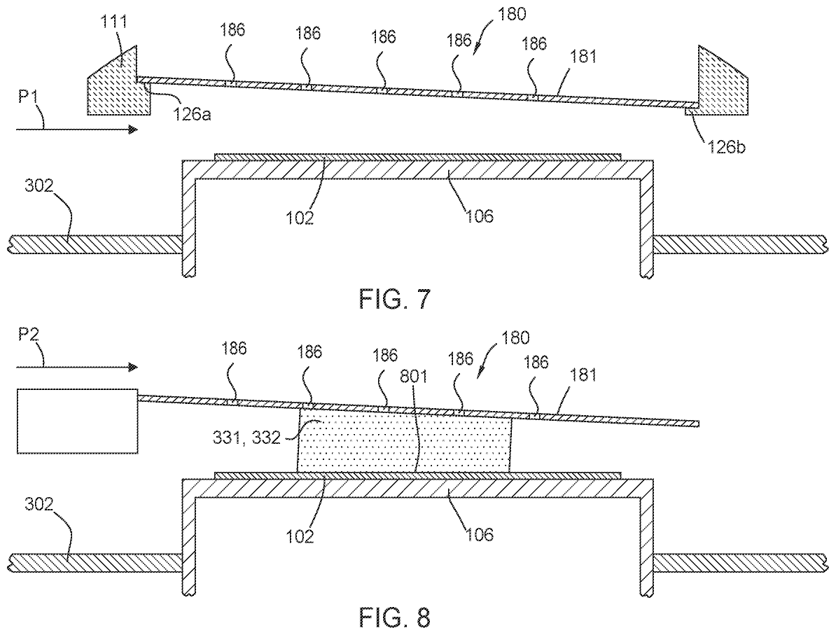

FIG. 7 is a schematic partial side cross-sectional view of first plate 180 shown in FIG. 5 in a tilted position, according to one or more embodiments. The first plate 180 is oriented in the tilted position such that the first plate 180 is oriented at an oblique angle relative to the substrate 102. In the embodiment shown in FIG. 7, a first ledge 125a has a height that is taller than a height of the first ledge 126b. The first ledge 125a can be angularly offset from one or more other ledges (such as the first ledge 125a) such that the first plate 180 can be raised, rotated, and lowered into the tilted position shown in FIG. 7. For example, the first plate 180 can be moved from a horizontal position (shown for example in FIG. 5) and to the tilted position. An upper surface of the first ledge 126 can be tapered (as shown for the first ledge 126a and/or 125b) to interface with the first plate 180 that contacts the ledges 125a, 125b. In one or more embodiments, the first plate 180 can be moved to the tilted position by raising the substrate support 106 to engage a first portion of the first plate 180 before engaging a second portion such that the first plate 180 is tilted by further raising of the substrate support 106. As an example, one of the first and second blocks 331, 332 (shown in FIG. 3) can be taller than the other of the first and second blocks 331, 332 such that the substrate support 106 engages the taller block before the other block.

FIG. 8 is a schematic partial side cross-sectional view of the first plate 180 shown in FIG. 5 in the tilted position, according to one or more embodiments. In one or more embodiments, the first plate 180 is coupled to the first block 331 and the second block 332. The first block 331 and the second block 332 each include a tapered lower surface 801 such that the raising of the substrate support 106 contacts a taller portion (having a first height) of each block 331, 332 prior to a shorter portion (having a second height) of each block 331, 332 such that further raising of the substrate support 106 tilts the first plate 180.

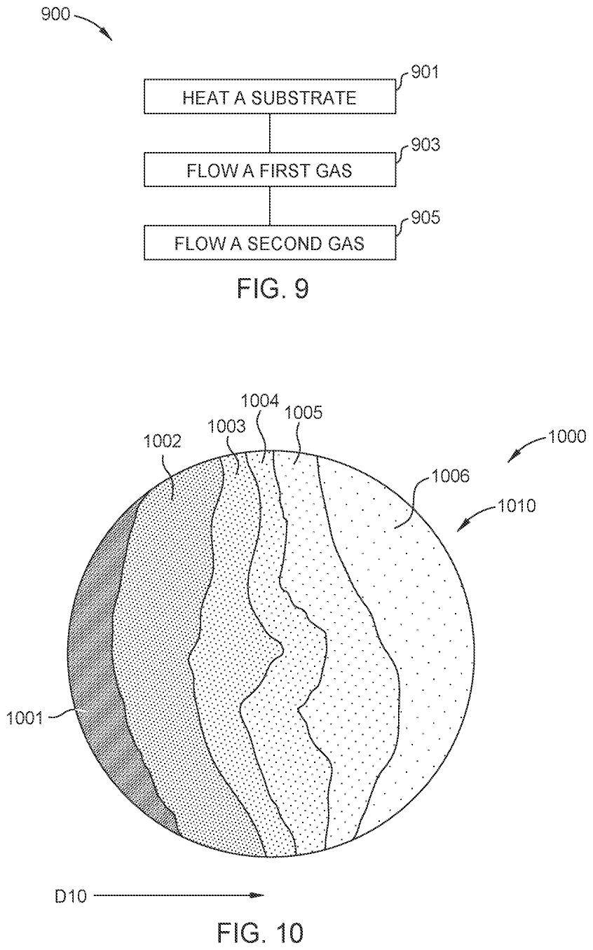

FIG. 9 is a schematic block diagram view of a method of substrate processing, suitable for use in semiconductor manufacturing.

Operation 901 of the method 900 includes heating a substrate disposed on a substrate support.

At operation 903, a first gas (such as the one or more process gases P1) is flowed into the process chamber. For example, the process gas P1 is flowed into the process volume 133 from one or more first supply openings 225. The process gas P1 may begin to deposit an epitaxial layer on the substrate 102.

At operation 905 a second gas (such as the one or more second gases P2 is flowed into the process chamber between two plates. For example, the second gas P2 is flowed into the process chamber 100 by a second supply opening 227, such that the second gas P2 flows between the first plate 180 and the second plate 182. During the deposition, the second gas P2 is flowed to the process volume 133 through the plurality of flow openings 186 to enhance deposition. The flow of the second gas at operation 905 can begin before, simultaneously with, or after the beginning of the flow of the first gas at operation 903.

In one or more embodiments, a third gas (such as the one or more third gases P3) is flowed to a third volume (such as the second volume 135) shown in FIG. 1) disposed between the second plate and a window opposite the first plate.

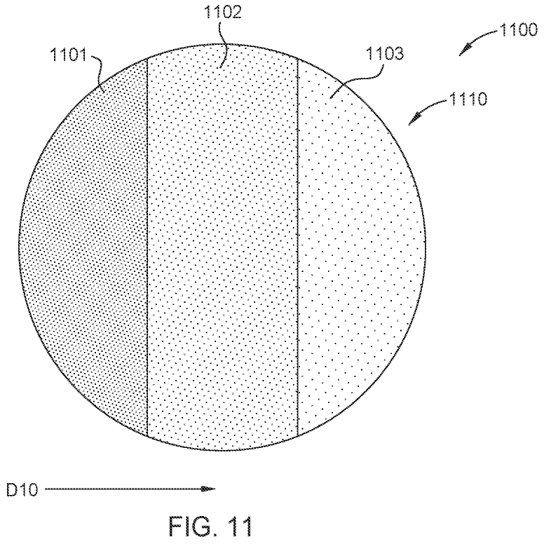

FIG. 10 illustrates schematically a deposition map 1000, according to one or more embodiments. The deposition map 1000 illustrates a thickness of a material deposited on a substrate. The thickness profile shown in FIG. 11 is believed to occur when a process does not use subject matter described herein. As shown, the deposition map 1000 includes a plurality of sections 1010. The plurality of sections 1010 include a first section 1001, a second section 1002, a third section 1003, a fourth section 1004, a fifth section 1005, and a sixth section 1006. A thickness of deposited material decreases along a direction of flow D10 across the sections 1010. The sections 1010 also experience varying flow rates of process gas which further leads to less uniformity of deposition. The sections 1010 also illustrate a less laminar gas flow than, for example, the sections 1110 shown in FIG. 11. This flow rate variability can be seen for example at the interfaces between the third section 1003 and the fourth section 1004. The erratic interface of the third section 1003 and the fourth section 1004 is a less linear line perpendicular to the direction of flow D10, which indicates a less laminar flow and a less uniform deposition which can partly be attributed to variations in flow rate across the substrate.

FIG. 11 illustrates schematically a deposition map 1100, according to one or more embodiments. The deposition map 1100 illustrates a thickness of a material deposited on a substrate. The thickness profile shown in FIG. 11 is believed to occur when a process includes subject matter described herein. As shown, the deposition map 1100 includes a plurality of sections 1110. The plurality of sections 1110 include a first section 1101, a second section 1102, and a third section 1103.

As shown, the thickness profile shown in FIG. 11 is more uniform than the thickness profile shown in FIG. 10. FIG. 11 also shows a more laminar flow of gases over the substrate than in FIG. 10. As such, the sections 1110 are believed to experience more flow rate uniformity and deposition uniformity due to the subject matter described. This uniformity can be seen by the fewer number of sections 1110 and by how the interfaces between the sections 1110 are more linear. The straight line interfaces between the sections 1110 are about perpendicular to the direction of flow D11, which indicates there is enhanced deposition uniformity and more laminar gas flow, which are facilitated by subject matter described herein.

Benefits of the present disclosure include enhanced deposition thicknesses; enhanced deposition uniformities; enhanced gas flow uniformities; more laminar gas flow; reduced coating of chamber components (such as the second plate 182, the first plate 180, and/or the upper window 108); adjustability of process parameters (such gas flow rate, temperature, and/or growth rate and process volume size); reduced cleaning; increased throughput and efficiency; and reduced chamber downtime.

It is contemplated that one or more aspects disclosed herein may be combined. As an example, one or more aspects, features, components, operations and/or properties of the processing chamber 100, the first plate 180, the second plate 182, the lower section 311 of the liner 111, the upper section 312 of the liner 111, the inlet and supply openings shown in FIG. 2A, the inlet and supply openings shown in FIG. 2B, the height adjustment system 301, the distance DA1, the distance DA2, the tilted positions shown in FIGS. 7 and 8, the method 900, and/or the information shown in the deposition map 1100 maybe be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A chamber kit for use in semiconductor manufacturing, the chamber kit comprising:
a liner comprising:
an inner face;
a first ledge disposed along the inner face; and
a second ledge disposed along the inner face, the second ledge spaced from the first ledge along the inner face;
a first plate sized and shaped to be disposed within the liner on the first ledge; and
a second plate sized and shaped to be disposed within the liner on the second ledge.

2. The chamber kit of claim 1, wherein the first plate comprises a plurality of flow openings.

3. The chamber kit of claim 2, wherein the second plate comprises a solid body having a solid cross section across an outer dimension of the second plate.

4. The chamber kit of claim 1, wherein a plurality of flow openings comprise a plurality of through holes extending through the first plate.

5. The chamber kit of claim 1, wherein the second plate comprises an outer diameter larger than an outer diameter of the first plate.

6. The chamber kit of claim 1, wherein:
the second ledge is disposed at a first distance between the first ledge and the second ledge; and
the liner further comprises a lower face disposed at a second distance between the first ledge and the lower face of the liner; and
the second distance is less than the first distance.

7. The chamber kit of claim 1, wherein the liner further comprises a first supply opening disposed outwardly of the first ledge, and a second supply opening disposed at least partially between the first ledge and the second ledge.

8. The chamber kit of claim 7, wherein the first supply opening is sized and shaped to open between the first plate and the second plate when the first plate and the second plate are disposed respectively on the first ledge and the second ledge.

9. The chamber kit of claim 8, wherein the first supply opening is aligned with a first exhaust outlet and the second supply opening is perpendicular to the first exhaust outlet.

10. The chamber kit of claim 1, wherein the first plate comprises transparent quartz.

11. The chamber kit of claim 10, wherein the first plate and the second plate are formed of transparent quartz.

12. A processing chamber for semiconductor manufacturing, the processing chamber comprising:
a chamber body;
one or more windows disposed within the chamber body;
a liner disposed within the chamber body;
a first plate disposed within the liner; and
a second plate disposed within the liner and spaced from the first plate, the second plate comprising a plurality of flow openings; and
a substrate support disposed within the chamber body to at least partially define a process volume between the first plate and the substrate support.

13. The processing chamber of claim 12, wherein the liner further comprises:
a first supply opening oriented to open to the process volume; and
a second supply opening oriented to open between the first plate and the second plate.

14. The processing chamber of claim 12, wherein the second plate has an outer diameter larger than an outer diameter of the first plate.

15. The processing chamber of claim 12, wherein a first flow opening of the plurality of flow openings is larger than a second flow opening of the plurality of flow openings.

16. The processing chamber of claim 12, wherein a first volume is between the first plate and the second plate, and the first volume is in fluid communication with the process volume through the plurality of flow openings.

17. The processing chamber of claim 16, wherein the second plate is disposed between the first volume and a second volume to fluidly isolate the first volume from the second volume.

18. A method of substrate processing, suitable for use in semiconductor manufacturing, the method comprising:
heating a substrate positioned on a substrate support;
flowing a first gas over a substrate in a process volume to deposit a material on the substrate;
flowing a second gas between a first plate and a second plate; and
flowing the second gas to the process volume through a plurality of flow openings formed in the first plate.

19. The method of claim 18, wherein the second gas is flowed perpendicular to the first gas through the plurality of flow openings to join the first gas in the process volume.

20. The method of claim 18, further comprising flowing a third gas to a volume disposed between the second plate and a window, wherein the second plate is disposed between the window and the first plate.
